(19) United States
(12) Patent Application Publication
(10) Pub. No.: US 2026/0344455 A1
(43) Pub. Date: Oct. 29, 2026

(54) SEMICONDUCTOR DEVICE MANUFACTURING METHOD AND SEMICONDUCTOR DEVICE

(71) Applicant: LINTEC CORPORATION, Tokyo (JP)

(72) Inventor: Shinya TAKYU, Tokyo (JP)

(73) Assignee: LINTEC CORPORATION, Tokyo (JP)

(21) Appl. No.: 19/704,921

(22) Filed: Jun. 11, 2026

Related U.S. Application Data
(63) Continuation of application No. PCT/JP2024/036680, filed on Oct. 15, 2024.

(30) Foreign Application Priority Data
Dec. 27, 2023 (JP) 2023-221612

(51) Int. Cl. H10W 46/00

(52) U.S. Cl. CPC H10W 46/401; H10W 46/103; H10W 46/603

(57) ABSTRACT

A semiconductor device manufacturing method comprises: a covering material preparing step 10 of preparing a covering material AS for covering a semiconductor body WF; an identification member preparing step 20 of preparing an identification member WK in which an identifier ID is formed; and a stacking step 50 of stacking the identification member WK on the semiconductor body WF with the covering material AS interposed therebetween to form a semiconductor device SD. In the covering material preparing step 10, one capable of adhering to both the semiconductor body WF and the identification member WK is prepared as the covering material AS. In the stacking step 50, the identification member WK is stacked on the semiconductor body WF in a state of bringing the identification member WK into direct contact with the covering material AS.

### BACKGROUND OF THE INVENTION

### Field of the Invention

The present invention relates to a semiconductor device manufacturing method and a semiconductor device.

### Description of the Related Art

In a semiconductor device having an identifier, when a small piece of an identification member is stacked on an IC chip, a space between a sealing resin covering the IC chip and the identification member is filled with an adhesive. Such a semiconductor device is required to be downsized in units of μm (micrometers) or nm (nanometers).

### SUMMARY OF THE INVENTION

The present invention disclosed and claimed herein, in one aspect thereof, comprises a method. The method comprises a covering material preparing step of preparing a covering material for covering a semiconductor body, in which a covering material capable of adhering to both the semiconductor body and an identification member is prepared as the covering material; an identification member preparing step of preparing an identification member in which an identifier is formed; and a stacking step of stacking the identification member on the semiconductor body with the covering material interposed therebetween to form a semiconductor device, in which the identification member is stacked on the semiconductor body in a state of bringing the identification member into direct contact with the covering material.

Further scope of applicability of the present invention will become apparent from the detailed description given hereinafter. The detailed description and embodiments are only given as examples though showing preferred embodiments of the present invention, and therefore, from the contents of the following detailed description, change and modifications of various kinds within the spirits and scope of the invention will become apparent to those skilled in the art.

### BRIEF DESCRIPTION OF THE DRAWINGS

The present invention will be fully understood from the following detailed description and the accompanying drawings. The accompanying drawings only show examples and are not intended to restrict the present invention. In the accompanying drawings:

FIGS. 1A - 1I are explanatory views of semiconductor device manufacturing units according to one embodiment, and

FIGS. 1J - 1M are explanatory views of modification examples.

### DETAILED DESCRIPTION

An embodiment will be hereinafter described based on the drawings.

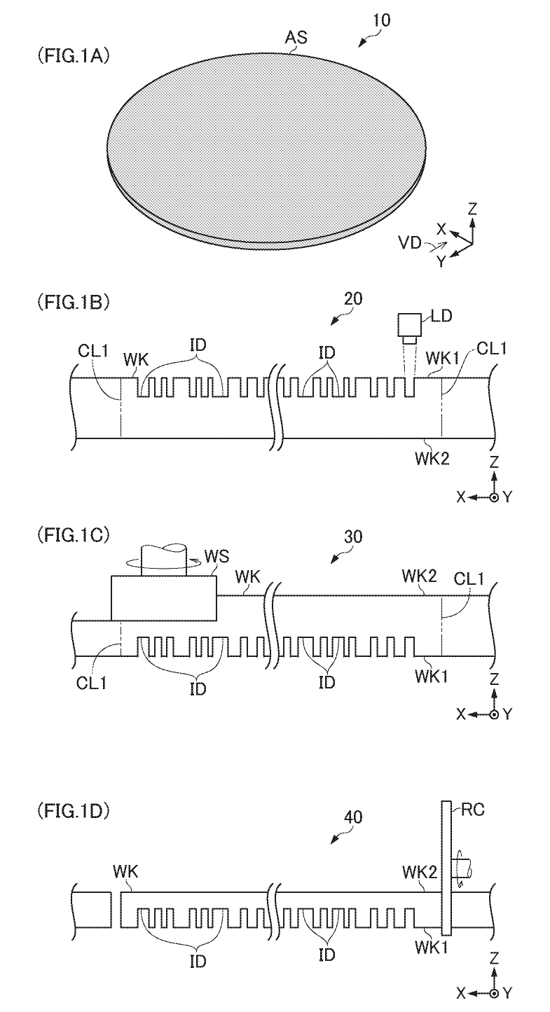

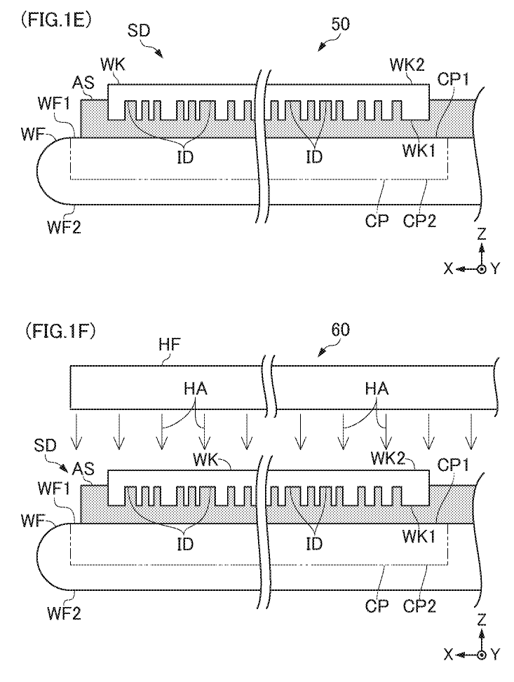

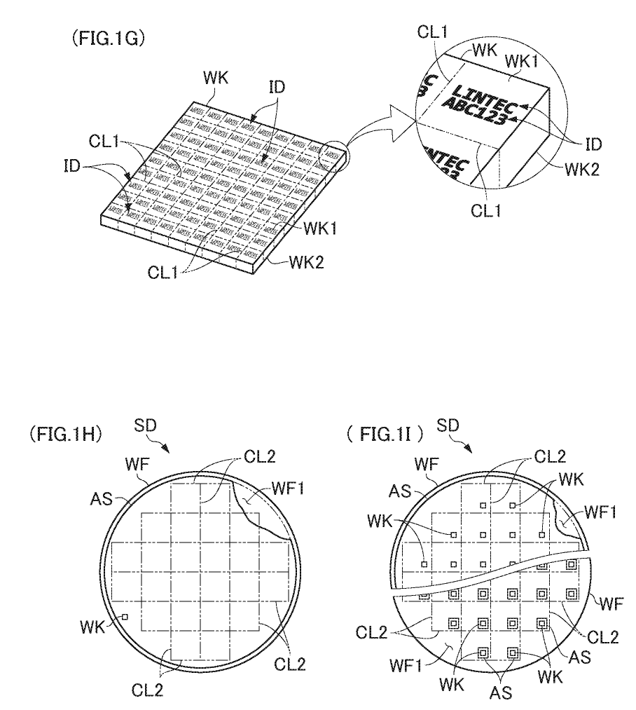

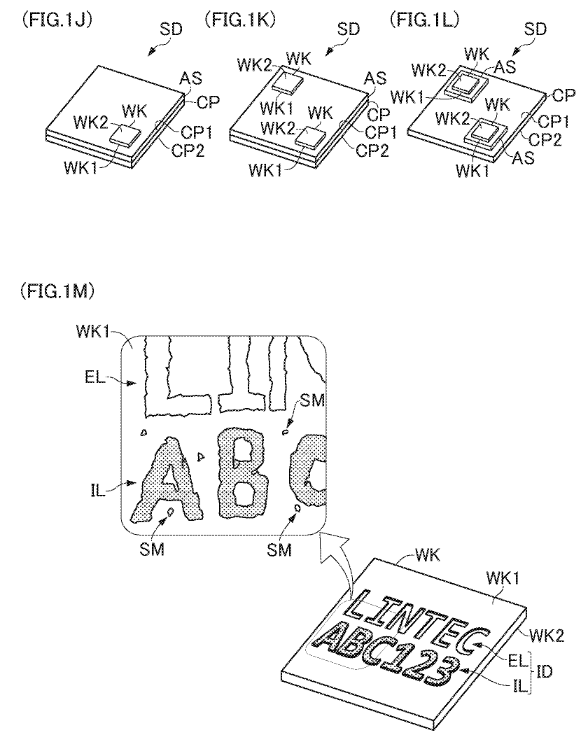

It should be noted that X-axis, Y-axis, and Z-axis in this embodiment are orthogonal to one another, where the X-axis and the Y-axis are within a predetermined plane while the Z-axis is orthogonal to the predetermined plane. Further, in this embodiment, the case of being viewed from the direction toward the near side in FIG. 1A is used as a reference for direction, and when a direction is mentioned without any designation of a drawing, an “upper” direction means a direction indicated by an arrow along the Z-axis, a “lower” direction means a direction opposite the “upper” direction, a “left” direction means a direction indicated by an arrow along the X-axis, a “right” direction means a direction opposite the “left” direction, a “front” direction means a direction indicated by an arrow along the Y-axis, and a “rear” direction means a direction opposite the “front” direction.

As illustrated in FIGS. 1A - 1F, a semiconductor device manufacturing method performs: a covering material preparing step 10 (see FIG. 1A) of preparing an adhesive sheet AS as a covering material for covering a semiconductor wafer (hereinafter also simply referred to as “wafer”) WF as a semiconductor body; an identification member preparing step 20 (see FIG. 1B) of preparing an identification member WK in which an identifier ID such as a character or a symbol is formed; a thinning step 30 (see FIG. 1C) of thinning a thickness of the identification member WK in a direction intersecting one surface WK1 thereof; a narrowing step 40 (see FIG. 1D) of narrowing a width of the identification member WK in a direction of the surface WK1 thereof; a stacking step 50 (see FIG. 1E) of stacking the identification member WK on the wafer WF with the adhesive sheet AS interposed therebetween to form a semiconductor device SD; and an energy applying step 60 (see FIG. 1F) of applying heat HA as a predetermined energy to the adhesive sheet AS.

Note that the wafer WF of this embodiment is composed of a silicon semiconductor.

In the covering material preparing step 10, one capable of adhering to both the wafer WF and the identification member WK is prepared as the adhesive sheet AS.

Note that the adhesive sheet AS of this embodiment has a property of undergoing curing as a change peculiar to the heat HA by application of the heat HA.

In the identification member preparing step 20, as illustrated in FIG. 1B, the identification member WK in which an identifier ID is formed in the surface WK1 by performing marking in a body constituting the identification member WK by a laser irradiation unit LD as an identifier forming unit is prepared (see FIG. 1G).

Note that the body constituting the identification member WK of this embodiment is composed of the same material as the wafer WF.

In the thinning step 30, as illustrated in FIG. 1C, the thickness of the identification member WK is thinned by grinding the other surface WK2 of the identification member WK with a grinder WS as a grinding machine.

Note that in the thinning step 30 of this embodiment, the thickness of the identification member WK is thinned so that the thickness of the identification member WK becomes 30 μm.

In the narrowing step 40, as illustrated in FIG. 1D, the width of the identification member WK is narrowed by cutting the identification member WK along a planned cutting line CL1 (see FIGS. 1C and 1G) with a rotary cutter RC as a cutting member.

Note that in the narrowing step 40 of this embodiment, the width of the identification member WK is narrowed so that the widths in the left-right direction and the front-rear direction become 100 μm.

In the stacking step 50, as illustrated in FIG. 1E, the identification member WK is stacked on the wafer WF in a state of bringing the identification member WK into direct contact with the adhesive sheet AS by adhering one surface WF1 of the wafer WF and the surface WK1 of the identification member WK with the adhesive sheet AS interposed therebetween (see FIGS. 1H and 1I).

Note that in the stacking step 50 of this embodiment, the identification member WK is stacked on the adhesive sheet AS such that a surface in which the identifier ID is formed is on the adhesive sheet AS side.

In the energy applying step 60, as illustrated in FIG. 1F, the adhesive sheet AS is cured by applying the heat HA to the adhesive sheet AS with a hot air blower HF.

In the semiconductor device SD formed through the above steps, the identifier ID is seen through from the other surface WK2 side of the identification member WK or the other surface WF2 side of the wafer WF, and thereby operations such as, for example, performing forgery detection or authenticity determination of the semiconductor device SD, or determining various processes to be performed on the semiconductor device SD, are performed.

According to the embodiment as described above, the one capable of adhering to both the wafer WF and the identification member WK is used as the adhesive sheet AS, and the identification member WK is stacked on the wafer WF in a state of bringing the identification member WK into direct contact with the adhesive sheet AS, and thus one that adheres the identification member WK and the adhesive sheet AS to each other becomes unnecessary therebetween, which allows a small-sized semiconductor device SD to be manufactured.

The structures and steps in the present invention are not limited at all as long as they can perform the operations, functions, or steps described for those structures and steps, and are certainly not limited to the components or steps of the mere one embodiment shown in the above-described embodiment. For example, the identification member preparing step may be any step as long as it is a step of preparing an identification member in which an identifier is formed, and is not limited at all as long as it is within the technical scope in light of the technical common sense at the time of filing (the same applies to other structures and steps).

Note that, as illustrated in FIGS. 1H - 1L, the semiconductor device SD may be one in which the identification member WK in which the identifier ID is formed is stacked on the wafer WF or a semiconductor chip (hereinafter also simply referred to as “chip”) CP as a semiconductor body with the adhesive sheet AS as a covering material interposed therebetween, and one in which the identification member WK is stacked on the wafer WF or the chip CP in a state where the identification member WK is in direct contact with the adhesive sheet AS, and which is formed through the above-described embodiment, each step exemplified below, or the like.

According to such a semiconductor device SD, the identification member is stacked on the wafer WF or the chip CP in a state where the identification member WK is in direct contact with the adhesive sheet AS, and thus to the extent that there is nothing to adhere the identification member WK and the adhesive sheet AS to each other, a small-sized semiconductor device SD can be obtained.

In the covering material preparing step 10, the adhesive sheet AS as the covering material for covering the chip CP as a semiconductor body may be prepared. Any material may be prepared as the covering material as long as one that can adhere to both the semiconductor body and the identification member WK, such as, for example, a pressure-sensitive adhesive sheet, an adhesive tape, a pressure-sensitive adhesive tape, an adhesive, a pressure-sensitive adhesive, a resin material, a rubber material, a metal material, solder, wax, or varnish, is provided. A solid substance may be prepared, a liquid substance may be prepared, or a gel-state substance may be prepared. A covering material larger than the semiconductor body may be prepared, a covering material smaller than the semiconductor body may be prepared, or a covering material having the same size as the semiconductor body may be prepared.

Regarding the covering material preparing step 10, it may be performed between the identification member preparing step 20 and the thinning step 30, may be performed between the thinning step 30 and the narrowing step 40, or may be performed between the narrowing step 40 and the stacking step 50. The covering material preparing step 10 may be performed at any stage as long as a timing enables the covering material to be prepared in a process of manufacturing the semiconductor device SD in which the identification member WK is stacked on the semiconductor body in a state of bringing the identification member WK into direct contact with the covering material.

In the identification member preparing step 20, the identifier ID may be formed in the body constituting the identification member WK by, for example, using a cutting member such as a cutter blade or high-pressure water, using a grinding member such as an end mill or a grinding stone, or using an etching technique such as wet etching or dry etching. Any unit may be employed as the identifier forming unit, such as an inkjet printer, a relief printing press, an intaglio printing press, a lithographic printing press, silk-screen printing, screen printing, a thermal printer, a thermal transfer printer, a dot impact printer, an exposure unit, an engraving unit, an etching unit, or a coloring unit. The identifier ID may be formed in the body constituting the identification member WK by marking, printing, print, transferring, exposure, engraving, etching, corrosion, coloring, discoloration, or the like. For example, any identifier ID, such as a character, a number, a symbol, a figure, a picture, a pattern, a scratch, or a hole, may be formed. The identifier ID capable of being identified by a combination of characters, symbols, or the like may be formed, the identifier ID capable of being identified by an arrangement, a font, or the like of characters, symbols, or the like may be formed, or the identifier ID capable of being identified by cryptic characters, cryptic symbols, or the like may be formed. For example, as illustrated in FIG. 1M, the identifier ID by a combination of characters EL formed by marking and characters IL formed by inkjet printing may be formed. For example, the identifier ID may be formed by appropriately combining a symbol formed by marking, a figure formed by printing, a number formed by inkjet printing, a pattern formed by end milling, or the like. For example, the identifier ID may be formed by only a picture formed by marking, only a character formed by printing, only a symbol formed by inkjet printing, only a number formed by end milling, or the like. For example, as illustrated in the enlarged view of FIG. 1M, the identifier ID capable of being identified by an irregular scraping state of a contour in the characters EL or the like formed by marking may be formed. For example, as illustrated in the enlarged view of FIG. 1M, the identifier ID capable of being identified by an irregular bleeding state of ink in the characters IL or the like formed by inkjet printing may be formed. For example, as illustrated in the enlarged view of FIG. 1M, the identifier ID capable of being identified by irregular scattered marks SM or the like due to scattering of ink by inkjet printing may be formed. The identifier ID may be formed only in the surface WK1 of the identification member WK, the identifier ID may be formed only in the other surface WK2 of the identification member WK, or the identifier ID may be formed in both the surface WK1 and the other surface WK2 of the identification member WK. One identifier ID may be formed in one identification member WK, or a plurality of identifiers ID may be formed in one identification member WK.

Regarding the identification member preparing step 20, it may be performed in a previous stage of the covering material preparing step 10, may be performed between the thinning step 30 and the narrowing step 40, may be performed between the narrowing step 40 and the stacking step 50, may be performed between the stacking step 50 and the energy applying step 60, or may be performed in a later stage of the energy applying step 60. The identification member preparing step 20 may be performed at any stage as long as a timing enables the identification member WK to be prepared in a process of manufacturing the semiconductor device SD in which the identification member WK is stacked on the semiconductor body in a state of bringing the identification member WK into direct contact with the covering material.

In the identification member preparing step 20, the identification member WK in which the identifier ID as described above is previously formed may be prepared without forming the identifier ID in a predetermined member, or the identification member WK in which any identifier ID is previously formed may be used, and the identification member WK may be prepared by further forming the identifier ID as described above in the identification member WK with the identifier forming unit.

In the thinning step 30, the thickness of the identification member WK may be thinned by employing, as the grinding machine, an electric file, a sander, a slicing machine, an electric cutter, a shearing machine, a pressing machine, a polishing unit, an etching unit, or the like to perform scraping, cutting, punching, polishing, dissolving, or etching. The thickness of the identification member WK may be thinned from the surface WK1 side of the identification member WK, the thickness of the identification member WK may be thinned from the other surface WK2 side of the identification member WK, or the thickness of the identification member WK may be thinned from both the surface WK1 side and the other surface WK2 side of the identification member WK. The thickness of the identification member WK may be thinned so that the thickness is smaller than 30 μm, such as 300 nm or 10 μm, or the thickness of the identification member WK may be thinned so that the thickness is larger than 30 μm, such as 100 μm or 1 mm, and the size and the shape are not limited.

Regarding the thinning step 30, it may be performed in a previous stage of the covering material preparing step 10, may be performed between the covering material preparing step 10 and the identification member preparing step 20, may be performed between the narrowing step 40 and the stacking step 50, may be performed between the stacking step 50 and the energy applying step 60, or may be performed in a later stage of the energy applying step 60. The thinning step 30 may be performed at any stage as long as a timing enables the thickness of the identification member WK to be thinned in a process of manufacturing the semiconductor device SD in which the identification member WK is stacked on the semiconductor body in a state of bringing the identification member WK into direct contact with the covering material. The thinning step 30 may be performed or need not be performed in the manufacturing method.

In the narrowing step 40, the width of the identification member WK may be narrowed by employing, as the cutting member, an electric file, a sander, a slicing machine, an electric cutter, a shearing machine, a pressing machine, a polishing unit, an etching unit, or the like to perform scraping, cutting, punching, polishing, dissolving, or etching. The width of the identification member WK may be narrowed from the surface WK1 side of the identification member WK, the width of the identification member WK may be narrowed from the other surface WK2 side of the identification member WK, or the width of the identification member WK may be narrowed from both the surface WK1 side and the other surface WK2 side of the identification member WK. The width in the surface WK1 direction of the identification member WK may be narrowed by forming a bottomed groove along a planned cutting line CL1 before performing the thinning step 30, and performing thinning until reaching the groove at the time of performing the thinning step 30. The width in the surface WK1 direction of the identification member WK may be narrowed by forming a weak layer along the planned cutting line CL1 before performing the thinning step 30, and causing a crack in the weak layer due to vibration at the time of performing the thinning step 30. The width of the identification member WK may be narrowed so that widths in the left-right direction and the front-back direction are each smaller than 100 μm, such as 0.5 μm or 50 μm, or the width of the identification member WK may be narrowed so that they are each larger than 100 μm, such as 500 μm or 3 mm. The width of the identification member WK may be narrowed so that the width in the left-right direction and the width in the front-back direction are the same, or the width of the identification member WK may be narrowed so that the width in the left-right direction and the width in the front-back direction are different. The width of the identification member WK may be narrowed so that the planar shape is any shape, such as a circular shape, an elliptical shape, a polygonal shape such as a triangular shape or a pentagonal shape, or other arbitrary shapes. The size and the shape are not limited.

Regarding the narrowing step 40, it may be performed in a previous stage of the covering material preparing step 10, may be performed between the covering material preparing step 10 and the identification member preparing step 20, may be performed between the identification member preparing step 20 and the thinning step 30, may be performed between the stacking step 50 and the energy applying step 60, or may be performed in a later stage of the energy applying step 60. The narrowing step 40 may be performed at any stage as long as a timing enables the width of the identification member WK to be narrowed in a process of manufacturing the semiconductor device SD in which the identification member WK is stacked on the semiconductor body in a state of bringing the identification member WK into direct contact with the covering material. The narrowing step 40 may be performed or need not be performed in the manufacturing method.

In the stacking step 50, as indicated by a two-dot chain line in FIG. 1E, the identification member WK may be stacked on the chip CP in a state of bringing the identification member WK into direct contact with the adhesive sheet AS such that the adhesive sheet AS is interposed between one surface CP1 of the chip CP and the surface WK1 of the identification member WK. The identification member WK may be stacked on the wafer WF or the chip CP in a state of bringing the identification member WK into direct contact with the adhesive sheet AS such that the adhesive sheet AS is interposed between the surface WF1 or the surface CP1 of the wafer WF or the chip CP and the other surface WK2 of the identification member WK. The identification member WK may be stacked on the wafer WF or the chip CP in a state of bringing the identification member WK into direct contact with the adhesive sheet AS such that the adhesive sheet AS is interposed between the other surface WF2 or the other surface CP2 of the wafer WF or the chip CP and the surface WK1 of the identification member WK. The identification member WK may be stacked on the wafer WF or the chip CP in a state of bringing the identification member WK into direct contact with the adhesive sheet AS such that the adhesive sheet AS is interposed between the other surface WF2 or the other surface CP2 of the wafer WF or the chip CP and the other surface WK2 of the identification member WK. The identification member WK may be stacked on the wafer WF or the chip CP in a state of bringing the identification member WK into direct contact with the adhesive sheet AS covering the whole or a part of the surface WF1 or the surface CP1 of the wafer WF or the chip CP. The identification member WK may be stacked on the wafer WF or the chip CP in a state of bringing the identification member WK into direct contact with the adhesive sheet AS covering the whole or a part of the other surface WF2 or the other surface CP2 of the wafer WF or the chip CP. The identification member WK may be stacked on the wafer WF or the chip CP in a state of bringing the identification member WK into direct contact with the adhesive sheet AS covering the whole or a part of the surface WF1 or the surface CP1 of the wafer WF or the chip CP and the whole or a part of the other surface WF2 or the other surface CP2 of the wafer WF or the chip CP. The identification member WK may be stacked on the wafer WF or the chip CP in a state of bringing the identification member WK into direct contact with the adhesive sheet AS covering the whole or a part of the surface WF1 or the surface CP1 of the wafer WF or the chip CP and the whole or a part of the side surface of the wafer WF or the chip CP. The identification member WK may be stacked on the wafer WF or the chip CP in a state of bringing the identification member WK into direct contact with the adhesive sheet AS covering the whole or a part of the other surface WF2 or the other surface CP2 of the wafer WF or the chip CP and the whole or a part of the side surface of the wafer WF or the chip CP. The identification member WK may be stacked on the wafer WF or the chip CP in a state of bringing the identification member WK into direct contact with the adhesive sheet AS covering the whole of the surface WF1, the whole of the other surface WF2, and the whole of the side surface of the wafer WF. The identification member WK may be stacked on the wafer WF or the chip CP in a state of bringing the identification member WK into direct contact with the adhesive sheet AS covering the whole of the surface CP1, the whole of the other surface CP2, and the whole of the side surface of the chip CP. The identification member WK may be stacked on the wafer WF or the chip CP in a state of bringing the identification member WK into direct contact with the adhesive sheet AS covering any surface of the wafer WF or the chip CP. The identification member WK may be stacked on the wafer WF or the chip CP by covering the wafer WF or the chip CP with the adhesive sheet AS and thereafter directly adhering the identification member WK to the adhesive sheet AS. The identification member WK may be stacked on the wafer WF or the chip CP by directly adhering the identification member WK to the adhesive sheet AS and thereafter covering the wafer WF or the chip CP with the adhesive sheet AS. The identification member WK may be stacked on the wafer WF or the chip CP by directly adhering the identification member WK to the adhesive sheet AS simultaneously with covering the wafer WF or the chip CP with the adhesive sheet AS.

In the stacking step 50, by employing, as the covering material, for example, a liquid adhesive, a liquid pressure-sensitive adhesive, or a liquid resin material and spraying or jetting them onto the wafer WF, the chip CP, or the identification member WK, the identification member WK may be stacked on the wafer WF or the chip CP in a state of bringing the identification member WK into direct contact with the covering material. As illustrated in FIGS. 1H and 1J, one identification member WK may be stacked on one wafer WF or one chip CP in a state of bringing the identification member WK into direct contact with one adhesive sheet AS. As illustrated in the upper part of FIGS. 1I and 1K, a plurality of identification members WK may be stacked on one wafer WF or one chip CP in a state of bringing the identification members WK into direct contact with one adhesive sheet AS. As illustrated in the lower part of FIGS. 1I and 1L, a plurality of identification members WK may be stacked on one wafer WF or one chip CP in a state of bringing the identification members WK into direct contact with a plurality of adhesive sheets AS, respectively. One identification member WK or a plurality of identification members WK may be stacked only on one surface or only on the other surface of one wafer WF or one chip CP in a state of bringing the identification member WK or the identification members WK into direct contact with one adhesive sheet AS or a plurality of adhesive sheets AS. One identification member WK or a plurality of identification members WK may be stacked on both one surface and the other surface of one wafer WF or one chip CP in a state of bringing the identification member WK or the identification members WK into direct contact with one adhesive sheet AS or a plurality of adhesive sheets AS.

Regarding the stacking step 50, it may be performed between the covering material preparing step 10 and the identification member preparing step 20, may be performed between the identification member preparing step 20 and the thinning step 30, may be performed between the thinning step 30 and the narrowing step 40, or may be performed in a later stage of the energy applying step 60. The stacking step 50 may be performed at any stage as long as a timing enables the identification member WK to be stacked on the semiconductor body with the covering material interposed therebetween in a process of manufacturing the semiconductor device SD in which the identification member WK is stacked on the semiconductor body in a state of bringing the identification member WK into direct contact with the covering material.

In the stacking step 50, when the identification member WK is stacked on the wafer WF with the adhesive sheet AS interposed therebetween, as illustrated in FIGS. 1E and 1F, the adhesive sheet AS may enter the whole of an inside of the identifier ID formed by marking, the adhesive sheet AS may enter a part of the inside of the identifier ID formed by marking, or the adhesive sheet AS may be prevented from entering the whole of the inside of the identifier ID formed by marking, or as illustrated in FIGS. 1E and 1F, a part of the identification member WK may be embedded in the adhesive sheet AS, the whole of the identification member WK may be embedded in the adhesive sheet AS, or the identification member WK may be prevented from being embedded in the adhesive sheet AS, or the identification member WK on the adhesive sheet AS may be covered with one equivalent to the covering material or a cover member such as a sheet or an adhesive different from the covering material.

In the energy applying step 60, any energy may be applied to the covering material as a predetermined energy, such as applying electromagnetic waves such as ultraviolet rays, infrared rays, visible light, sound waves, X-rays, or gamma rays, applying a heating medium such as hot water or hot air, or applying a cooling medium such as cold water or cold air. Any energy may be applied to the covering material as long as it can cause a change peculiar to the energy in the covering material in consideration of characteristics, attributes, properties, materials, compositions, configurations, and the like of the covering material.

Regarding the energy applying step 60, it may be performed between the covering material preparing step 10 and the identification member preparing step 20, may be performed between the identification member preparing step 20 and the thinning step 30, may be performed between the thinning step 30 and the narrowing step 40, or may be performed between the narrowing step 40 and the stacking step 50. The energy applying step 60 may be performed at any stage as long as a timing enables the predetermined energy to be applied to the adhesive sheet AS in a process of manufacturing the semiconductor device SD in which the identification member WK is stacked on the semiconductor body in a state of bringing the identification member WK into direct contact with the covering material. The energy applying step 60 may be performed or need not be performed in the manufacturing method.

The body constituting the identification member WK may be composed of the same material as a material constituting the semiconductor body, or may be composed of a material different from the material constituting the semiconductor body. In addition to materials such as a silicon semiconductor and a compound semiconductor, the body may be composed of any material, such as metal, glass, ceramics, wood, or resin.

The covering material may be any material as long as it is one capable of adhering to both the semiconductor body and the identification member WK, such as, for example, a pressure-sensitive adhesive sheet, an adhesive tape, a pressure-sensitive adhesive tape, an adhesive, a pressure-sensitive adhesive, a resin material, a rubber material, a metal material, solder, wax, or varnish. The covering material may be a solid substance, may be a liquid substance, or may be a gel-state substance. The covering material may be larger than the semiconductor body, may be smaller than the semiconductor body, or may have the same size as the semiconductor body. The covering material may have any shape, such as, for example, a polygonal shape such as a triangular shape or a pentagonal shape, or an elliptical shape, besides a circular shape. The covering material may be one that does not undergo a change peculiar to the predetermined energy by application of the predetermined energy.

The change peculiar to the predetermined energy that the covering material undergoes may be any change, such as, for example, curing, softening, shrinking, expansion, vaporization, liquefaction, solidification, discoloration, oxidation, penetration, fixing, a decrease in adhesive strength, or an increase in adhesive strength.

In the wafer WF, an orientation flat or a V-notch indicating an orientation may be formed at an outer edge thereof, or the orientation flat or the V-notch need not be formed at the outer edge. The wafer WF may be one in which a circuit is formed on the surface WF1, may be one in which a circuit is formed on the other surface WF2, may one in which circuits are formed on both the surface WF1 and the other surface WF2, or may be one in which a circuit is formed on neither the surface WF1 nor the other surface WF2.

The chip CP may be one obtained by cutting the wafer WF along a cutting line CL2, or need not be one obtained by cutting the wafer WF along the cutting line CL2. The chip CP may be one in which a circuit is formed on one surface CP1, may be one in which a circuit is formed on the other surface CP2, may be one in which circuits are formed on both the surface CP1 and the other surface CP2, or may be one in which a circuit is formed on neither the surface CP1 nor the other surface CP2.

As the semiconductor body, for example, one thinned from a thickness such as 1 mm or 750 μm to a thickness such as 100 μm or 10 μm may be employed in the stacking step 50. For example, one having a thickness such as 2 mm or 500 μm may be employed in the stacking step 50, and it may be thinned to a thickness such as 150 μm or 20 μm by performing a semiconductor thinning step in a later stage of the stacking step 50.

The various processes for the semiconductor device SD may be any process, such as an installation process for installing the semiconductor device SD on another object, a marking process for performing marking or printing in the semiconductor device SD, a transport process for transporting the semiconductor device SD, a cutting process or a grinding process of the semiconductor device SD, or inspection, cleaning, or the like of the semiconductor device SD.

The semiconductor device SD as illustrated in FIG. 1H may be cut along the cutting line CL2, thereby being formed as a semiconductor device SD in which the adhesive sheet AS is attached to the chip CP, or need not be cut.

The semiconductor device SD as illustrated in the upper part of FIG. 1I may be cut along the cutting line CL2, thereby being formed as a semiconductor device SD as illustrated in FIG. 1J, or need not be cut.

The semiconductor device SD as illustrated in the lower part of FIG. 1I may be cut along the cutting line CL2, or need not be cut.

Materials, types, shapes, and the like of the identification member WK, the covering material, and the semiconductor body in the present invention are not particularly limited. For example, the identification member WK, the covering material, and the semiconductor body may be circular, elliptical, polygonal such as triangular or quadrangular, or have other shapes. The covering material may be of an adhesive form such as pressure-sensitive adhesiveness or heat-sensitive adhesiveness, and when the covering material of the heat-sensitive adhesiveness is employed, it needs only to be adhered by an appropriate method such as providing a heater such as an appropriate coil heater or a heating side of a heat pipe that heats the covering material. Further, such an adhesive sheet as the covering material may be any sheet, such as, for example, a single-layer one having only an adhesive layer, a two-layer one in which a base material and an adhesive layer are stacked, a three-layer or three-or-more-layer one in which one intermediate layer or a plurality of intermediate layers are stacked between a base material and an adhesive layer, a three-layer or three-or-more-layer one in which one cover layer or a plurality of cover layers are stacked on an upper surface of a base material, one in which a base material, an intermediate layer, or a cover layer is provided to be peelable, a single-layer double-sided adhesive sheet consisting only of an adhesive layer, or a double-sided adhesive sheet in which adhesive layers are stacked on both outermost surfaces of one intermediate layer or a plurality of intermediate layers. Note that the covering material may be any sheet, film, tape, or the like, such as, for example, an information-description label, a decorative label, a protective sheet, a dicing tape, a die-attach film, a die-bonding tape, or a recording-layer-forming resin sheet. Further, the semiconductor body may be any semiconductor, such as a silicon semiconductor, a compound semiconductor, or a diamond semiconductor.

What is claimed is:

1. A semiconductor device manufacturing method comprising:
a covering material preparing step of preparing a covering material for covering a semiconductor body, in which a covering material capable of adhering to both the semiconductor body and an identification member is prepared as the covering material;
an identification member preparing step of preparing an identification member in which an identifier is formed; and
a stacking step of stacking the identification member on the semiconductor body with the covering material interposed therebetween to form a semiconductor device, in which the identification member is stacked on the semiconductor body in a state of bringing the identification member into direct contact with the covering material.

2. The method according to claim 1, further comprising:
a thinning step of thinning a thickness in a direction intersecting one surface of the identification member.

3. The method according to claim 1, further comprising:
a narrowing step of narrowing a width in a direction of one surface of the identification member.

4. The method according to claim 1, wherein
the covering material has a property of undergoing a change peculiar to a predetermined energy by application of the predetermined energy, and
the method further comprising an energy applying step of applying the predetermined energy to the covering material.

5. The method according to claim 1, wherein
in the stacking step, the identification member is stacked on the covering material such that the identifier is on the covering material side.

6. The method according to claim 5, further comprising:
a thinning step of thinning a thickness in a direction intersecting one surface of the identification member.

7. The method according to claim 5, further comprising:
a narrowing step of narrowing a width in a direction of one surface of the identification member.

8. The method according to claim 5, wherein
the covering material has a property of undergoing a change peculiar to a predetermined energy by application of the predetermined energy, and
the method further comprising an energy applying step of applying the predetermined energy to the covering material.

9. A semiconductor device comprising:
a semiconductor body in which an identification member in which an identifier is formed is stacked with a covering material interposed therebetween, and the identification member being in a state of being in direct contact with the covering material.
